(19) United States
(12) Patent Application Publication
(10) Pub. No.: US 2025/0309873 A1
(43) Pub. Date: Oct. 2, 2025

(54) APPARATUS AND METHOD FOR GENERATING MULTI-LEVEL HIGH VOLTAGE NON-SINUSOIDAL SIGNAL IN SEMICONDUCTOR MANUFACTURING EQUIPMENT USING PLASMA

(71) Applicant: DAWONSYS CO., LTD., Ansan-si Gyeonggi-do (KR)

(72) Inventors: Young Woo KIM, Ansan-si (KR); Min Ho JUNG, Ansan-si (KR)

(21) Appl. No.: 19/235,888

(22) Filed: Jun. 12, 2025

Related U.S. Application Data
(63) Continuation of application No. PCT/KR2023/020550, filed on Dec. 13, 2023.

(30) Foreign Application Priority Data
Dec. 13, 2022 (KR) 10-2022-0174226

(51) Int. Cl. H03K 4/26; H01J 37/32

(52) U.S. Cl. CPC H03K 4/26; H01J 37/32128

(57) ABSTRACT

According to the present embodiment, provided is a non-sinusoidal signal generation apparatus comprising: a first rectangular wave circuit, which can apply, to an output terminal, two positive voltages having different magnitudes; a second rectangular wave circuit, which can apply, to the output terminal, two negative voltages having different magnitudes; and a sawtooth wave circuit, which can apply, to the output terminal, two sawtooth wave voltages having different magnitudes, wherein the sawtooth wave circuit comprises an inductor for drawing current from a capacitive load connected to the output terminal.

### CROSS-REFERENCE TO RELATED APPLICATION

The present application is a continuation of International Application No. PCT/KR2023/020550, filed on Dec. 13, 2023, which is based upon and claims priority to Korean Patent Application No. 10-2022-0174226, filed on Dec. 13, 2022 in Korea. The entire disclosure of the above application is incorporated herein by reference.

### TECHNICAL FIELD

The present embodiment relates to an apparatus and a method for generating a multi-level high voltage non-sinusoidal signal in semiconductor manufacturing equipment using plasma.

### BACKGROUND

The description below merely provides background information related to the present embodiment and does not constitute the prior art.

Existing voltage generators are generally configured to generate a monotonous level of output voltages at an output terminal, making it difficult to apply the existing voltage generators to environments where it is required to generate various levels of output voltages.

In addition, even when the voltage generators are implemented to generate various levels of voltages, a circuit configuration where circuitry is not complicated is required.

Thus, a method is required for improving the performance of equipment equipped with the voltage generators, in an economic and precise manner, by precisely controlling various levels of output voltages output from the voltage generators, such as a low voltage level and a high voltage level.

### SUMMARY

An aspect of the present invention is to provide an apparatus and a method for generating a multi-level high voltage non-sinusoidal signal in semiconductor manufacturing equipment using plasma.

According to the present embodiment, there is provided a non-sinusoidal signal generation apparatus comprising: a first rectangular wave circuit, which can apply, to an output terminal, two positive voltages having different magnitudes; a second rectangular wave circuit, which can apply, to the output terminal, two negative voltages having different magnitudes; and a sawtooth wave circuit, which can apply, to the output terminal, two sawtooth wave voltages having different magnitudes, wherein the sawtooth wave circuit comprises an inductor for drawing current from a capacitive load connected to the output terminal.

According to the present embodiment, there is provided a method for generating a non-sinusoidal signal by an apparatus including a first rectangular wave circuit, a second rectangular wave circuit, and a sawtooth wave circuit, the method comprising: applying a first positive voltage to an output terminal by the first rectangular wave circuit; applying a first negative voltage to the output terminal by the second rectangular wave circuit; applying a first sawtooth wave voltage to the output terminal by the sawtooth wave circuit; applying a second positive voltage to the output terminal by the first rectangular wave circuit; applying a second negative voltage to the output terminal by the second rectangular wave circuit; and applying a second sawtooth wave voltage to the output terminal by the sawtooth wave circuit, wherein, when the first sawtooth wave voltage or the second sawtooth wave voltage is applied, current is drawn from a capacitive load connected to the output terminal by using an inductor included in the sawtooth wave circuit.

According to the present embodiment, there is provided an apparatus for manufacturing a semiconductor device comprising a non-sinusoidal signal generation apparatus and a chamber, wherein the non-sinusoidal signal generation apparatus comprises: a first rectangular wave circuit, which can apply, to an output terminal, two positive voltages having different magnitudes; a second rectangular wave circuit, which can apply, to the output terminal, two negative voltages having different magnitudes; and a sawtooth wave circuit, which can apply, to the output terminal, two sawtooth wave voltages having different magnitudes, wherein the sawtooth wave circuit comprises an inductor for drawing current from a capacitive load connected to the output terminal.

The present invention has an effect of providing an apparatus for manufacturing a semiconductor device and a non-sinusoidal signal generation apparatus where various outputs can be generated by selectively generating relatively low-voltage rectangular wave and sawtooth wave signals, in addition to high-voltage rectangular wave and sawtooth wave signals, through switching of a multi-level voltage circuit.

### BRIEF DESCRIPTION OF THE DRAWINGS

FIG. 1 is a schematic block diagram of a non-sinusoidal signal generation apparatus and a capacitive load, according to the present embodiment.

FIG. 2 is a circuit diagram of the non-sinusoidal signal generation apparatus according to a first embodiment.

FIGS. 3A to 3F are circuit diagrams illustrating an operation of the non-sinusoidal signal generation apparatus according to the first embodiment.

FIG. 4 is a diagram illustrating a waveform of output Vout of an output terminal Nout in switching sections D1, D2, D3, D4, D5, D6, corresponding to the circuits of FIGS. 3A to 3F.

FIGS. 5A to 5C are diagrams illustrating an operation method of the non-sinusoidal signal generation apparatus according to the first embodiment.

FIGS. 6A to 6C are diagrams illustrating a method of determining an inductance of an inductor L included in the non-sinusoidal signal generation apparatus according to the first embodiment.

FIG. 7 is a circuit diagram of a non-sinusoidal signal generation apparatus according to a second embodiment, excluding a controller.

FIG. 8 is a circuit diagram of a non-sinusoidal signal generation apparatus according to a third embodiment, excluding a controller.

FIG. 9 is a circuit diagram of a non-sinusoidal signal generation apparatus according to a fourth embodiment, excluding a controller.

FIG. 10 is a flowchart of a method for generating a non-sinusoidal signal according to the present embodiment.

FIG. 11 is a diagram illustrating an example of a non-sinusoidal signal generation apparatus implemented by connecting a plurality of first rectangular wave circuits, a plurality of second rectangular wave circuits, and a plurality of sawtooth wave circuits in series.

FIG. 12 is a diagram illustrating an example of a non-sinusoidal signal generation apparatus implemented by connecting a plurality of first rectangular wave circuits, a plurality of second rectangular wave circuits, and one sawtooth wave circuit in parallel.

FIG. 13 is a diagram illustrating an example of a non-sinusoidal signal generation apparatus implemented by connecting a plurality of first rectangular wave circuits, a plurality of second rectangular wave circuits, and a plurality of sawtooth wave circuits in parallel.

FIGS. 14A and 14B are block diagrams of an apparatus 1400 for manufacturing a semiconductor device according to the present embodiment.

### REFERENCE NUMERALS

100, 700, 800, 900: non-sinusoidal signal generation apparatus
110, 710, 810, 910: first rectangular wave circuit
120, 720, 820, 920: second rectangular wave circuit
130, 730, 830, 930: sawtooth wave circuit
140: controller 200: capacitive load

### DETAILED DESCRIPTION

Hereinafter, some embodiments of the present invention are described in detail with reference to the drawings. It should be noted that, when assigning identification symbols to the components in each drawing, the same components have the same symbols as much as possible even if they are indicated in different drawings. In addition, when it is determined herein that the specific description of related known components or functions can obscure the gist of the present invention, the detailed description thereof will be omitted.

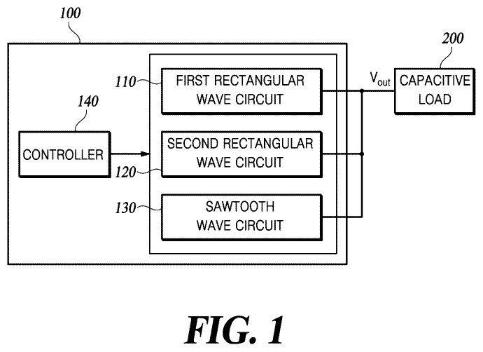

FIG. 1 is a schematic block diagram of a non-sinusoidal signal generation apparatus 100 and a capacitive load 200, according to the present embodiment.

The non-sinusoidal signal generation apparatus 100 may generate an output voltage Vout having a certain waveform set by a user, and the generated output voltage Vout may be provided to the capacitive load 200. For example, the capacitive load 200 includes a chamber CB as semiconductor manufacturing equipment using plasma.

The output waveform of the non-sinusoidal signal generation apparatus 100 may have a frequency of several kHz to several MHz and may be output at any variable voltage level of several tens of V to several tens of kV.

The non-sinusoidal signal generation apparatus 100 may include a first rectangular wave circuit 110, a second rectangular wave circuit 120, at least one sawtooth wave circuit 130, and a controller 140.

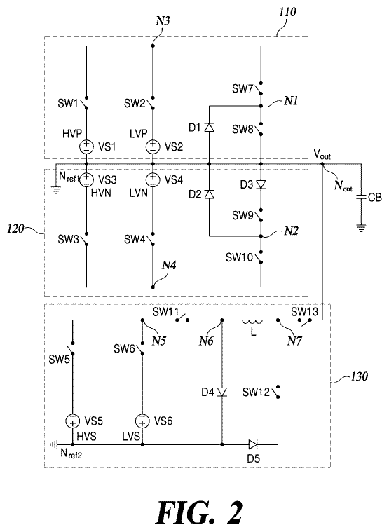

FIG. 2 is a circuit diagram of the non-sinusoidal signal generation apparatus 100 according to a first embodiment.

In FIG. 2, the controller 140 is omitted from among the components of the non-sinusoidal signal generation apparatus 100.

The first rectangular wave circuit 110 is configured to apply two positive voltages having different magnitudes to the output terminal.

The second rectangular wave circuit 120 is configured to apply two negative voltages having different magnitudes to the output terminal.

The sawtooth wave circuit 130 is configured to apply two sawtooth wave voltages having different magnitudes to the output terminal and includes an inductor or a current source configured to draw current from a capacitive load connected to the output terminal (i.e., discharge the capacitive load).

Referring to FIG. 2, the first rectangular wave circuit 110, the second rectangular wave circuit 120, and the sawtooth wave circuit 130 may be connected in parallel between the output terminal Nout that outputs the output voltage Vout and a ground GND that provides a reference potential. The chamber CB may be further connected to the output terminal Nout, where the chamber CB may be modeled as the capacitive load, e.g., a capacitor.

The first rectangular wave circuit 110 may include a first voltage source VS1, a second voltage source VS2, a first switch SW1, a second switch SW2, a seventh switch SW7, an eighth switch SW8, and a first diode D1.

The second rectangular wave circuit 120 may include a third voltage source VS3, a fourth voltage source VS4, a third switch SW3, a fourth switch SW4, a ninth switch SW9, a tenth switch SW10, a second diode D2, and a third diode D3.

A circuit where the first voltage source VS1 and the first switch SW1 are connected in series is referred to as a first voltage source circuit, a circuit where the second voltage source VS2 and the second switch SW2 are connected in series is referred to as a second voltage source circuit, a circuit where the third voltage source VS3 and the third switch SW3 are connected in series is referred to as a third voltage source circuit, and a circuit where the fourth voltage source VS4 and the fourth switch SW4 are connected in series is referred to as a fourth voltage source circuit.

The first and second voltage source circuits that respectively generate two positive voltages having different magnitudes may be connected to a first reference terminal Nref1. The first reference terminal Nref1 may be connected to the ground GND to provide a reference potential (e.g., 0 potential) to the non-sinusoidal signal generation apparatus 100. The negative terminals of the first and second voltage source circuits may be connected to the first reference terminal Nref1, and the positive terminals of the first and second voltage source circuits are connected to a third node N3 in parallel.

The negative terminal of the first voltage source circuit refers to a terminal of the first voltage source circuit in a negative terminal direction of the first voltage source VS1, the positive terminal of the first voltage source circuit refers to a terminal of the first voltage source circuit in a positive terminal direction of the first voltage source VS1, the negative terminal of the second voltage source circuit refers to a terminal of the second voltage source circuit in a negative terminal direction of the second voltage source VS2, and the positive terminal of the second voltage source circuit refers to a terminal of the second voltage source circuit in a positive terminal direction of the second voltage source VS2.

The first and second voltage sources VS1 and VS2 may output first and second voltages V1 and V2, respectively, having different magnitudes. The first and second voltage sources VS1 and VS2 may be DC voltage sources, but may have variable values. In addition, a magnitude of the first voltage V1 may be greater than or less than that of the second voltage V2.

In the second rectangular wave circuit 120, a positive terminal of the third voltage source circuit and a positive terminal of the fourth voltage source circuit are each connected to the first reference terminal Nref1, and a negative terminal of the third voltage source circuit and a negative terminal of the fourth voltage source circuit are each connected to one end of the tenth switch SW10, that is, a fourth node N4.

The negative terminal of the third voltage source circuit refers to a terminal of the third voltage source circuit in a negative terminal direction of the third voltage source VS3, the positive terminal of the third voltage source circuit refers to a terminal of the third voltage source circuit in a positive terminal direction of the third voltage source VS3, the negative terminal of the fourth voltage source circuit refers to a terminal of the fourth voltage source circuit in a negative terminal direction of the fourth voltage source VS4, and the positive terminal of the fourth voltage source circuit refers to a terminal of the fourth voltage source circuit in a positive terminal direction of the fourth voltage source VS4.

The third and fourth voltage sources VS3 and VS4 may output third and fourth voltages V3 and V4 having different magnitudes, respectively. The third and fourth voltage sources VS3 and VS4 may be DC voltage sources, but may have variable values. In addition, a magnitude of the third voltage V3 may be greater than or less than that of the fourth voltage V4.

The seventh switch SW7 is connected between the third node N3 and the first node N1, and the eighth switch SW8 is connected between the first node N1 and the output terminal Nout. That is, the positive terminal (i.e., the third node N3) of the first voltage source circuit is connected to one end of the seventh switch SW7, and the other end of the seventh switch SW7 is connected to the first node N1. In addition, one end of the eighth switch SW8 is connected to the first node N1, and the other end of the eighth switch SW8 is connected to the output terminal Nout.

The tenth switch SW10 is connected between the negative terminal (i.e., the fourth node N4) of the third voltage source circuit and the second node N2, and the ninth switch SW9 is connected between the second node N2 and the output terminal Nout. That is, the negative terminal of the third voltage source circuit is connected to one end of the tenth switch SW10, and the other end of the tenth switch SW10 is connected to the second node N2. In addition, one end of the ninth switch SW9 is connected to the second node N2, and the other end of the ninth switch SW9 is connected to the output terminal Nout.

The first diode D1 may be connected between the first reference terminal Nref1 and the first node N1. An anode of the first diode D1 may be connected to the first reference terminal Nref1, and a cathode of the first diode D1 may be connected to the first node N1.

The second diode D2 may be connected between the first reference terminal Nref1 and the second node N2. A cathode of the second diode D2 may be connected to the first reference terminal Nref1, and an anode of the second diode D2 may be connected to the second node N2.

The third diode D3 may be connected between the output terminal Nout and the other end of the ninth switch SW9. An anode of the third diode D3 may be connected to the output terminal Nout, and a cathode of the third diode D3 may be connected to the other end of the ninth switch SW9.

When the seventh and eighth switches SW7 and SW8 are turned on and the ninth and tenth switches SW9 and SW10 are turned off, the first voltage V1 or the second voltage V2 having different positive magnitudes may be output to the output terminal Nout. In this state, when the first switch SW1 is turned on and the second switch SW2 is turned off, the positive first voltage V1 may be output to the output terminal Nout, and when the first switch SW1 is turned off and the second switch SW2 is turned on, the positive second voltage V2 may be output to the output terminal Nout.

When the ninth and tenth switches SW9 and SW10 are turned on and the seventh and eighth switches SW7 and SW8 are turned off, the third voltage V3 or the fourth voltage V4 having different negative magnitudes may be output to the output terminal Nout. In this state, when the third switch SW3 is turned on and the fourth switch SW4 is turned off, the negative third voltage V3 may be output to the output terminal Nout, and when the third switch SW3 is turned off and the fourth switch SW4 is turned on, the negative fourth voltage V4 may be output to the output terminal Nout.

When the eighth switch SW8 is turned on and the seventh, tenth, and ninth switches SW7, SW10, and SW9 are turned off, or when the ninth switch SW9 is turned on and the seventh, eighth, and tenth switches SW7, SW8, and SW10 are turned off, a ground GND voltage or a zero voltage may be output to the output terminal Nout.

Accordingly, voltages of five different levels 0, V1, V2, V3, and V4 may be output to the output terminal Nout.

The sawtooth wave circuit 130 may include a fifth voltage source VS5, a sixth voltage source VS6, a fifth switch SW5, a sixth switch SW6, an eleventh switch SW11, a twelfth switch SW12, a thirteenth switch SW13, a fourth diode D4, a fifth diode D5, and an inductor L.

A circuit where the fifth voltage source VS5 and the fifth switch SW5 are connected in series is referred to as a fifth voltage source circuit, and a circuit where the sixth voltage source VS6 and the sixth switch SW6 are connected in series is referred to as a sixth voltage source circuit.

In the sawtooth wave circuit 130, a positive terminal of each of the fifth voltage source circuit and the sixth voltage source circuit, which is connected to a second reference terminal Nref2 to generate two negative voltages having different magnitudes, is connected in parallel to one end of the eleventh switch SW11, that is, the fifth node N5. The second reference terminal Nref2 may be connected to the ground GND that provides a reference potential.

For reference, when the first reference terminal Nef1 and the second reference terminal Nef2 are each connected to the ground GND, the ground GND may be expressed as a reference terminal.

The negative terminal of the fifth voltage source circuit refers to a terminal of the fifth voltage source circuit in a negative terminal direction of the fifth voltage source VS5, the positive terminal of the fifth voltage source circuit refers to a terminal of the fifth voltage source circuit in a positive terminal direction of the fifth voltage source VS5, the negative terminal of the sixth voltage source circuit refers to a terminal of the sixth voltage source circuit in a negative terminal direction of the sixth voltage source VS6, and the positive terminal of the six voltage source circuit refers to a terminal of the six voltage source circuit in a positive terminal direction of the sixth voltage source VS6.

The fifth voltage source VS5 and the sixth voltage source VS6 output a fifth voltage V5 and a sixth voltage V6, respectively. The fifth and sixth voltages V5 and V6 may be DC voltage sources or may be variable voltage sources. In addition, the magnitude of the fifth voltage V5 may be greater than or less than that of the sixth voltage V6.

One end of the eleventh switch SW11 is connected to the negative terminal (i.e., the fifth node N5) of the fifth voltage source circuit, the fourth diode D4 is connected between the other end (i.e., the sixth node N6) of the eleventh switch SW11 and the second reference terminal Nref2, one end of the inductor L is connected to the other end of the eleventh switch SW11, the twelfth switch SW12 and the fifth diode D5 are connected in series between the other end of inductor L (i.e., a seventh node N7) and the second reference terminal Nref2, and the thirteenth switch SW13 is connected between the other end of the inductor L and the output terminal Nout.

An anode of the fourth diode D4 may be connected to the sixth node N6, and a cathode of the fourth diode D4 may be connected to the second reference terminal Nref2.

The sawtooth wave circuit 130 may generate a sawtooth wave voltage (i.e., a slope voltage) by charging the inductor L current using the fifth voltage source VS5 or the sixth voltage source VS6 and then drawing the current from the chamber CB to change the voltage of the chamber CB, as described below.

The inductor L may be connected between the sixth node N6 and the seventh node N7. The inductor L may have an inductance determined according to values of the first to sixth voltages V1, V2, V3, V4, V5, and V6.

The first to thirteenth switches SW1, SW2, SW3, SW4, SW5, SW6, SW7, SW8, SW9, SW10, SW11, SW12, and SW13 may be power semiconductor devices. The power semiconductor device, which is a semiconductor device used for power conversion or control, may be implemented as a device, such as an insulated gate bipolar transistor (IGBT) or a metal-oxide semiconductor field effect transistor (MOSFET).

In addition, the controller 140 generates drive signals for turning the first to thirteenth switches SW1, SW2, SW3, SW4, SW5, SW6, SW7, SW8, SW9, SW10, SW11, SW12, and SW13 on or off.

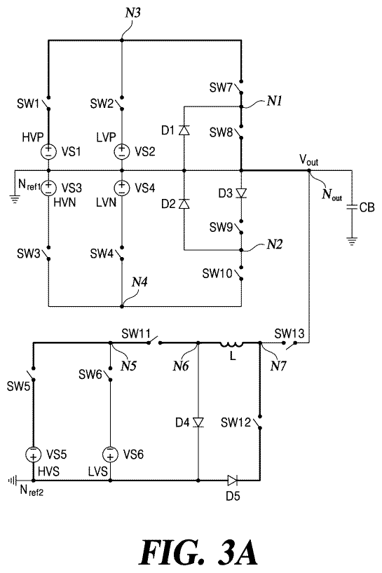

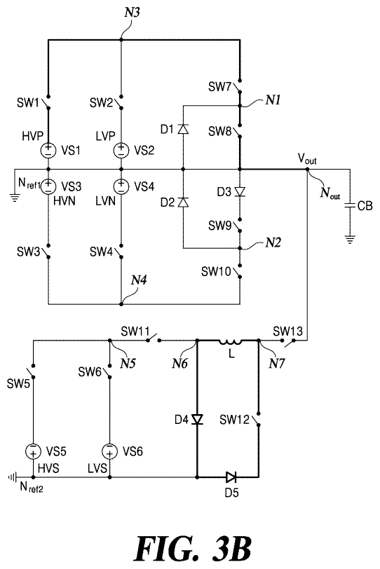

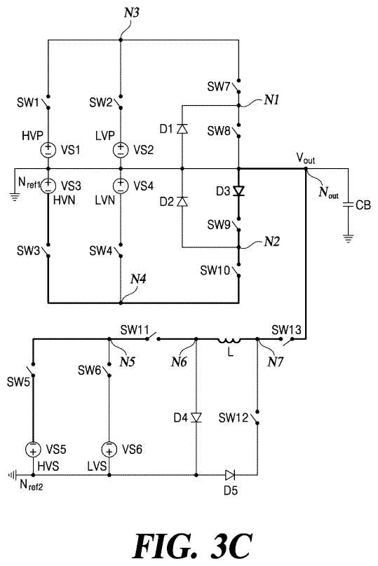

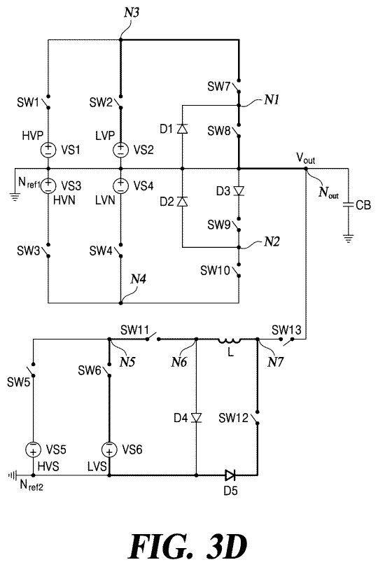

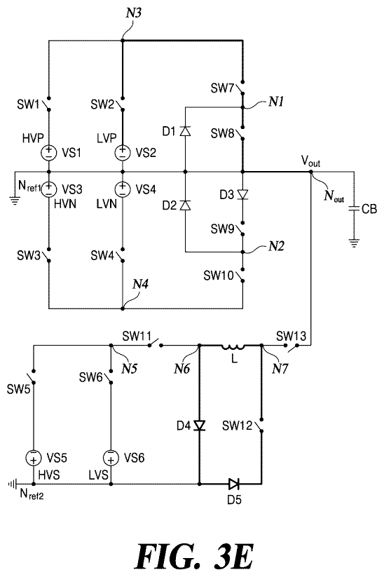

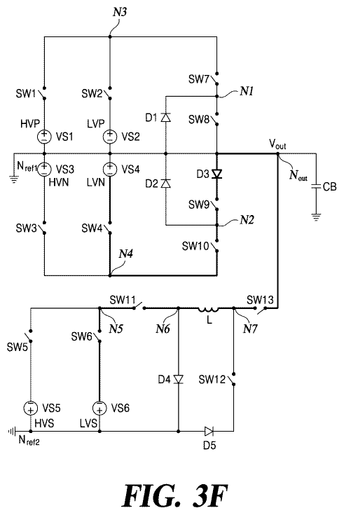

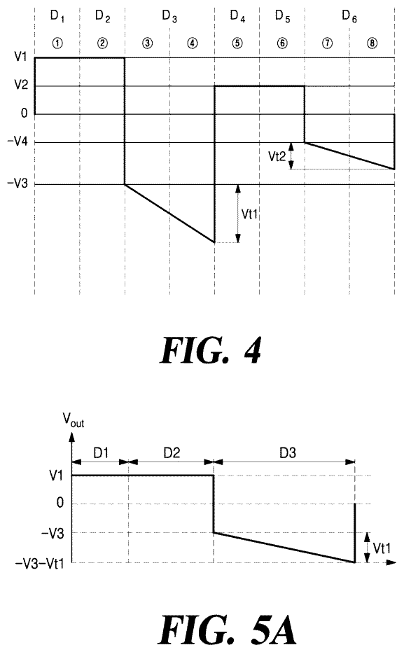

FIGS. 3A to 3F are circuit diagrams illustrating an operation of the non-sinusoidal signal generation apparatus 100, and FIG. 4 is a diagram illustrating a waveform of outputs Vout of the output terminal Nout in switching sections D1, D2, D3, D4, D5, and D6 corresponding to the circuits of FIGS. 3A and 3F.

Referring to FIGS. 3A to 3F and FIG. 4, FIGS. 3A to 3F are diagrams illustrating switching states of a circuit with respect to a section D1, a section D2, a section D3, a section D4, a section D5, and a section D6, respectively.

In FIG. 3A, the first switch SW1, the seventh switch SW7, the eighth switch SW8, the fifth switch SW5, the eleventh switch SW11, and the twelfth switch SW12 are turned on and all the other switches are turned off to form a circuit illustrated by a thick line in FIG. 3A.

In FIG. 3A, the positive terminal of the first voltage source VS1 may be connected to the output terminal Nout via the first, seventh, and eighth switches SW1, SW7, and SW8. Accordingly, the first voltage V1 may be applied as the output voltage Vout. In addition, as a path composed of the fifth voltage source VS5, the fifth diode D5, the twelfth switch SW12, the inductor L, the eleventh switch SW11, and the fifth switch SW5 is formed, the inductor L may be charged by the fifth voltage source VS5 through the path. At this time, as a closed path passing through the second voltage source VS2, the third voltage source VS3, the fourth voltage source VS4, and the sixth voltage source VS6 is not formed, the second voltage source VS2, the third voltage source VS3, the fourth voltage source VS4, and the sixth voltage source VS6 may be floated.

In FIG. 3B, as the first switch SW1, the seventh switch SW7, the eighth switch SW8, and the twelfth switch SW12 are in an on state and all the other switches are in an off state, a circuit illustrated by a thick line in FIG. 3B is formed.

In FIG. 3B, the positive terminal of the first voltage source VS1 may be connected to the output terminal Nout via the first, seventh, and eighth switches SW1, SW7, and SW8. Accordingly, the first voltage V1 may be applied as the output voltage Vout. In addition, as a closed path composed of the inductor L, the fourth diode D4, the fifth diode D5, and the twelfth switch SW12 is formed, the current of the inductor L may flow continuously. At this time, as a closed path passing through the second voltage source VS2, the third voltage source VS3, the fourth voltage source VS4, the fifth voltage source VS5, and the sixth voltage source VS6 is not formed, the second voltage source VS2, the third voltage source VS3, the fourth voltage source VS4, the fifth voltage source VS5, and the sixth voltage source VS6 may be floated.

In FIG. 3C, as the third switch SW3, the ninth switch SW9, the tenth switch SW10, the fifth switch SW5, the eleventh switch SW11, and the thirteenth switch SW13 are in an on state and all the other switches are in an off state, a circuit illustrated by a thick line in FIG. 3C is formed.

In FIG. 3C, the negative terminal of the third voltage source VS3 may be connected to the output terminal Nout via the third, tenth, and ninth switches SW3, SW10, and SW9. Accordingly, the third voltage V3 may be applied as the output voltage Vout. In addition, the negative terminal of the fifth voltage source VS5 is connected to the output terminal Nout via the fifth switch SW5, the eleventh switch SW11, the inductor L, and the thirteenth switch SW13. Therefore, the fifth voltage V5 having a negative magnitude and the voltage by the inductor L current may be applied to the output terminal Nout. At this time, as a closed path passing through the first voltage source VS1, the second voltage source VS2, the fourth voltage source VS4, and the sixth voltage source VS6 is not formed, the first voltage source VS1, the second voltage source VS2, the fourth voltage source VS4, and the sixth voltage source VS6 may be floated.

In FIG. 3C, current substantially equal to the inductor L current may flow into the sawtooth wave circuit 130 from the chamber CB modeled as a capacitive load. At this time, a voltage change according to Equation 1 below may occur in the chamber CB.

$${C}_{CB} \frac{{dV}_{out}}{dt} = Is \qquad [ Equation 1 ]$$

C_{CB} is an equivalent capacitance of the chamber CB, and Is may correspond to current flowing from the chamber to the inductor L.

Accordingly, since the voltage applied to the chamber CB is lower than the voltage provided by the third voltage source VS3 (i.e., a negative voltage with a greater absolute value), a sawtooth wave shape (slope) may be formed in the output voltage Vout.

At this time, the current may not substantially flow from the second rectangular wave circuit 120 to the chamber CB due to the operation of the third diode D3. Specifically, since the voltage of the cathode of the third diode D3 becomes lower than the voltage of the anode thereof due to the decrease in the output voltage Vout, the current may not flow from the second rectangular wave circuit 120 to the chamber CB. Accordingly, the current may flow only from the chamber CB to the sawtooth wave circuit 130.

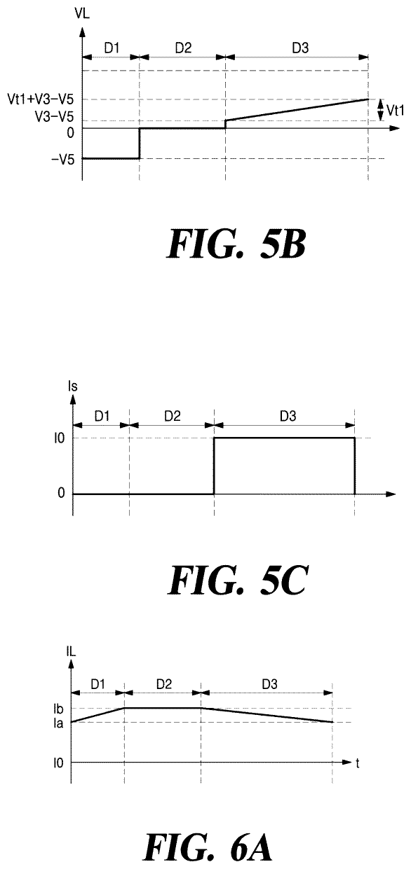

FIGS. 5A to 5C are diagrams illustrating an operation method of the non-sinusoidal signal generation apparatus 100.

FIG. 5A is a graph illustrating the output voltage Vout of the output terminal Nout corresponding to each section of FIGS. 3A to 3C over time. FIG. 5B is a graph illustrating the voltage VL at both ends of the inductor L corresponding to each section of FIGS. 3A to 3C over time. FIG. 5C is a graph illustrating the current Is flowing from the chamber CB to the sawtooth wave circuit 130 corresponding to each section of FIGS. 3A to 3C over time.

Referring to FIGS. 3A to 3C and 5A, as the first voltage source VS1 is connected to the output terminal Nout via the first, seventh, and eighth switches SW1, SW7, and SW8 during the first and second sections D1 and D2, the output voltage Vout may be substantially the same as the first voltage V1.

Then, the change in the output voltage Vout according to Equation 1 occurs due to the current flowing out of the chamber CB, which is a capacitive load, during the third section D3, and the magnitude of the change in the output voltage Vout during the third section D3, that is, the difference between the maximum value and the minimum value of the output voltage Vout during the third section D3, is referred to as Vt1. The output voltage Vout is shown to change from an absolute value to a greater negative value, but is not limited thereto.

Referring to FIGS. 3A to 3C and 5B, since the inductor L is charged by the fifth voltage source VS5 during the first section D1, the voltage of the fifth voltage source VS5 is applied between both ends of the inductor L and no voltage is applied during the second section D2. During the third section D3, a voltage corresponding to a voltage difference between the output voltage Vout and the fifth voltage V5 may be applied between both ends of the inductor L.

When the circuit starts to operate and reaches a normal state after a sufficient period of time has elapsed, the inductor L current is periodic, and as shown in Equation 2, the result of periodic integration of the voltage at both ends the inductor L may be 0.

$${\int }_{0}^{D 1 + D 2 + D 3} V L dt = - V 5 \cdot D 1 = 0 \cdot D 2 + ( - ( - V 3 ) - V 5 + \frac{1}{2} Vt ) \cdot D 3 \qquad [ Equation 2 ]$$

The description with respect to Vt1 is as shown in Equation 3 below.

$$Vt = 2 ( 1 + \frac{D 1}{D 3} ) V 5 - 2 V 3 \qquad [ Equation 3 ]$$

Therefore, the magnitude of Vt1 may be controlled by adjusting the length of the first section D1 and the magnitudes of the third and fifth voltages V3 and V5. When the sum of the lengths of the first to third sections D1, D2, and D3 is constant, the ratio of the length of the first section D1 to the length of the third section D3 may be changed according to the length of the second section D2, thereby generating a sawtooth wave voltage having various slopes. For example, when the length of the sum D1+D2 of the first and second sections D1 and D2 is kept constant and the length of the first section D1 is increased while the length of the second section D2 is decreased, the slope of the sawtooth wave voltage may be increased. Conversely, when the length of the sum D1+D2 of the first and second sections D1 and D2 is kept constant and the length of the first section D1 is decreased while the length of the second section D2 is increased, the slope of the sawtooth wave voltage may be decreased.

Referring to FIGS. 3A to 3C and 5C, no electrical path is formed from the chamber CB to the sawtooth wave circuit 130 during the first to second sections D1 and D2, and thus no current may flow. During the third section D3, as an electrical path passing through the fifth voltage source VS5, the fifth switch SW5, the eleventh switch SW11, the inductor L, the thirteenth switch SW13, and the chamber CB is formed, the current may flow from the chamber CB to the sawtooth wave circuit 130. At this time, by determining the inductance of the inductor L in consideration of the values of the first, third, and fifth voltages V1, V3, and V5 and the lengths of the first to third sections D1, D2, and D3, the value of the current Is flowing from the chamber CB to the sawtooth wave circuit 130 during the third section D3 may be maintained at a substantially constant current value I0. However, the present invention is not limited thereto, and the current value flowing from the chamber CB to the sawtooth wave circuit 130 during the third section D3 may vary.

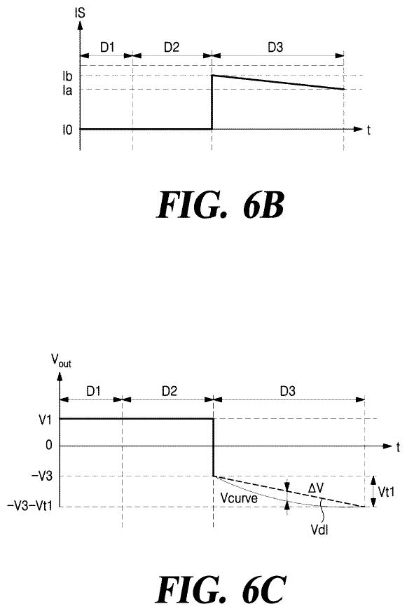

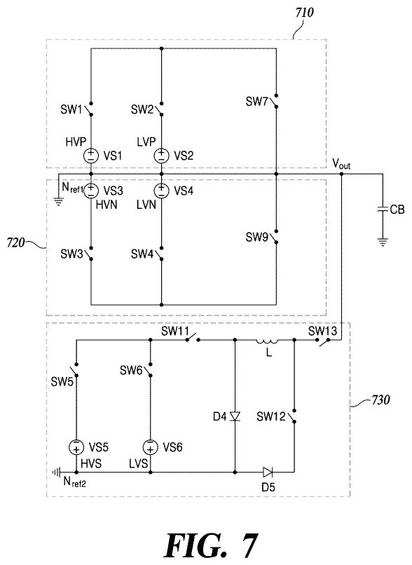

FIGS. 6A to 6C are diagrams illustrating a method of determining the inductance of the inductor L included in the non-sinusoidal signal generation apparatus 100.

FIG. 6A is a diagram illustrating the inductor current IL over time for each of the first to third sections D1, D2, and D3 in FIGS. 3A to 3C. Unlike that shown in FIG. 6A, the substantial inductor current IL may be increased by applying the first voltage V1 during the first section D1, may be maintained at a constant value during the second section D2, and may be decreased during the third section D3.

When a sufficient time elapses after the controller 140 starts to drive the first to thirteenth switches SW1 to SW13, the inductor current IL may reach a normal state and the amount of increase in the inductor current IL during the first section D1 may be substantially the same as the amount of decrease in the inductor current IL during the third section D3. Assuming that the value of the inductor current IL at the start of the first section D1 is Ia and the value of the inductor current IL at the end of the first section D1 is Ib, Ia and Ib satisfy Equation 4 with respect to the fifth voltage V5.

$$Ib - Ia = \frac{V 5 \cdot D 1}{La} \qquad [ Equation 4 ]$$

La is the inductance of the inductor L.

Referring to FIGS. 6A and 6B, when it is assumed that the inductor current IL and the chamber current Is are the same and the inductor L current changes linearly during the third section D3, the chamber current Is may be represented by Equation 5 below.

$$Is = IL = Ib + ( Ia + Ib ) ( \frac{t - D 1 - D 2}{D 3} ) \qquad [ Equation 5 ]$$

t refers to time.

Referring to FIG. 6C, the output voltage Vout of the third section D3 changed by the current in Equation 5 may be curved, unlike the output voltage Vout of the third section D3 in FIG. 5A, which is referred to as a curved voltage Vcurve.

The curved voltage Vcurve according to Equation 5 becomes a second-order polynomial with respect to time, and the linear voltage Vdl and the curved voltage Vcurve have the same value at the start point and the end point of the third section D3. It may be seen that when the primary equation and the secondary equation meet at two points through the differential operation, the maximum value of the difference appears at the midpoint of the two points. Accordingly, assuming that the maximum value of the difference between the linear voltage Vdl and the curved voltage Vcurve is ΔV, ΔV satisfies Equation 6 below.

$${C}_{CB} \cdot Δ V = ( Ib - Ia ) \cdot \frac{D 3}{8} = \frac{V 3 \cdot D 1}{La} \cdot \frac{D 3}{8} \qquad [ Equation 6 ]$$

The description with respect to the inductance La is as shown in Equation 7 below.

$$La = \frac{D 1 \cdot D 3}{8 {C}_{CB}} . \frac{V 3}{Δ V} \qquad [ Equation 7 ]$$

Accordingly, as the value of the inductance La increases, the output voltage Vout of the third section D3 may change to a shape close to a straight line. When the maximum value or the upper limit of the deviation from the actual output curved voltage Vcurve and the linear voltage Vdl is determined, the inductance value La may be determined accordingly.

In FIGS. 3D and 3E, unlike in FIGS. 3A and 3B, as the first switch SW1 is turned off and the second switch SW2 is turned on, the second voltage source VS2 and the second switch SW2 in the second voltage source circuit are connected to the circuit to operate, instead of the first voltage source VS1 and the first switch SW1 in the first voltage source circuit. In addition, in FIG. 3D, unlike in FIG. 3A, as the fifth switch SW5 is turned off and the sixth switch SW6 is turned on, the sixth voltage source VS6 and the sixth switch SW6 in the sixth voltage source circuit are connected to the circuit to operate, instead of the fifth voltage source VS5 and the fifth switch SW5 in the fifth voltage source circuit.

The operation in FIGS. 3D and 3E may be described, by replacing the first voltage source VS1 with the second voltage source VS2, replacing the first switch SW1 with the second switch SW2, replacing the fifth voltage source VS5 with the sixth voltage source VS6, and replacing the fifth switch SW5 with the sixth switch SW6, with reference to FIGS. 3A and 3B. Thus, further detailed description is omitted.

The operation in FIG. 3F may be described, by replacing the third voltage source VS3 with the fourth voltage source VS4, replacing the third switch SW3 with the fourth switch SW4, replacing the fifth voltage source VS5 with the sixth voltage source VS6, and replacing the fifth switch SW5 with the sixth switch SW6, with reference to FIG. 3C. Thus, further detailed description is omitted.

However, with respect to the operation of FIGS. 3D to 3F, the voltage V2 of the second voltage source VS2 may be less than the voltage V1 of the first voltage source VS1, the voltage V4 of the fourth voltage source VS4 may be less than the voltage V3 of the third voltage source VS3, and the voltage V6 of the sixth voltage source VS6 may be less than the voltage V5 of the fifth voltage source VS5. In addition, corresponding to the difference between the maximum value and the minimum value of the output voltage Vout during the third section D3 being referred to as Vt1, the difference between the maximum value and the minimum value of the output voltage Vout during the sixth section D6 is referred to as vt2, wherein the vt2 has a value less than vt1. In addition, with respect to the description of Equations 1 to 7, D4 may be substituted for D1, D5 may be substituted for D2, D6 may be substituted for D3, V4 may be substituted for V3, and Vt2 may be substituted for Vt1.

Thus, it may be seen that the non-sinusoidal waves occurring as a result of the operations of FIGS. 3A to 3C have a less magnitude that those occurring as a result of the operations of FIGS. 3D to 3F.

On the other hand, two voltage source circuits may be omitted herein. That is, one voltage source circuit (one of the third voltage source circuit and the fourth voltage source circuit) in the second rectangular wave circuit 120 and one voltage source circuit (one of the fifth voltage source circuit and the sixth voltage source circuit) in the sawtooth wave circuit 130 may be omitted.

FIG. 7 is a circuit diagram of a non-sinusoidal signal generation apparatus 700 according to a second embodiment, excluding a controller (not shown). Even in FIG. 7, the controller (not shown) controls each switch by generating drive signals to turn on or off each switch.

The non-sinusoidal signal generation apparatus 700 includes a first rectangular wave circuit 710, a second rectangular wave circuit 720, and a sawtooth wave circuit 730.

Referring to FIG. 2 and FIG. 7, in the non-sinusoidal signal generation apparatus 700 according to the second embodiment, the first diode D1 and the second diode D2 are omitted, compared to the non-sinusoidal signal generating apparatus 100 according to the first embodiment, only the seventh switch SW7 is present in the non-sinusoidal signal generation apparatus 700 according the second embodiment at a position where the seventh and eighth switches SW7 and SW8 are present in the non-sinusoidal signal generation apparatus 100 according to the first embodiment, and only the ninth switch SW9 is present in the non-sinusoidal signal generation apparatus 700 according to the second embodiment at a position where the third diode D3, the ninth switch SW9, and the tenth switch SW10 are present in the non-sinusoidal signal generation apparatus 100 according the first embodiment. The other components in the non-sinusoidal signal generation apparatus 100 according to the first embodiment are connected in the same manner as those in the non-sinusoidal signal generating apparatus 700 according to the second embodiment.

In the above description with reference to FIG. 2, when the seventh switch SW7 and the eighth switch SW8 of FIG. 2 are turned off or on at the same time, it may be described in FIG. 7 that the seventh switch SW7 is controlled to be turned off or on. In addition, in the above description with reference to FIG. 2, when the ninth switch SW9 and the tenth switch SW10 of FIG. 2 are turned off or on at the same time, it may be described in FIG. 7 that the ninth switch SW9 is controlled to be turned off or on.

Therefore, in addition to descriptions of the ninth switch SW9 and the tenth switch SW10 in FIG. 7, the other components and on or off driving timings of other switches are the same as those described above with reference to FIG. 2. Thus, further detailed description is omitted.

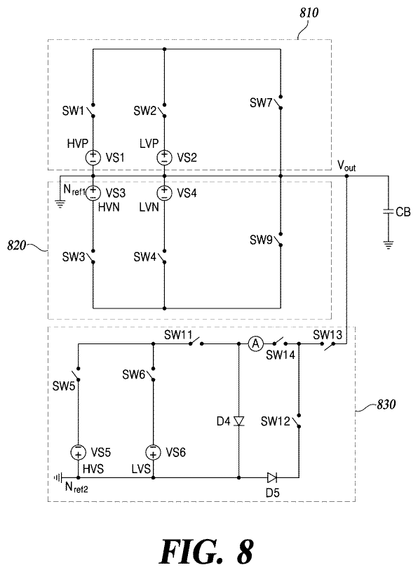

FIG. 8 is a circuit diagram of a non-sinusoidal signal generation apparatus 800 according to a third embodiment, excluding a controller (not shown). Even in FIG. 8, the controller (not shown) controls each switch by generating drive signals, thereby turning on or off each switch.

The non-sinusoidal signal generation apparatus 800 includes a first rectangular wave circuit 810, a second rectangular wave circuit 820, and a sawtooth wave circuit 830.

In FIG. 8, unlike in FIG. 7, a current source A and a fourteenth switch SW14 connected in series are arranged, instead of the inductor L, and the other components in FIG. 8 are connected in the same manner as in FIG. 7. The fourteenth switch SW14 may be turned on only during sections D3 and D6 and may be turned off during sections D1, D2, D4, and D5. The on or off driving timing for each switch, except for the fourteenth switch SW14, in FIG. 8 is the same as that in FIG. 7. Thus, further detailed description with reference to FIG. 8 is omitted.

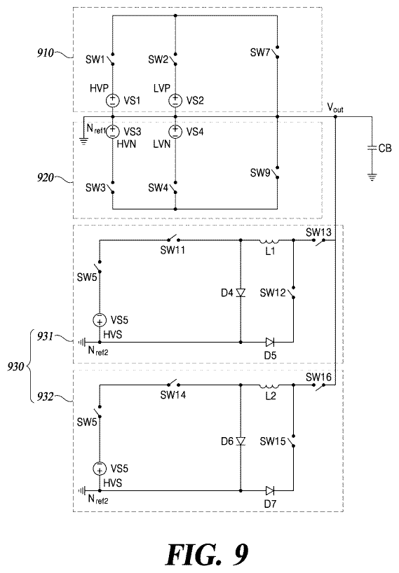

FIG. 9 is a circuit diagram of a non-sinusoidal signal generation apparatus 900 according to a fourth embodiment, excluding a controller (not shown). Even in FIG. 9, the controller (not shown) controls each switch by generating drive signals, thereby turning on or off each switch.

The non-sinusoidal signal generation apparatus 900 includes a first rectangular wave circuit 910, a second rectangular wave circuit 920, and a sawtooth wave circuit 930.

The first rectangular wave circuit 910 has the same configuration and connection form as the first rectangular wave circuit 710 in the second embodiment, and the second rectangular wave circuit 920 has the same configuration and connection form as the second rectangular wave circuit 720 in the second embodiment. Therefore, further descriptions of the first rectangular wave circuit 910 and the second rectangular wave circuit 920 are omitted.

The sawtooth wave circuit 930 includes a first sawtooth wave circuit 931 and a second sawtooth wavelength circuit 932.

The first sawtooth wave circuit 931 is the same as the sawtooth wave circuit 730 in the non-sinusoidal signal generation apparatus 700 according to the second embodiment, except that the sixth voltage source VS6 and the sixth switch SW6 are removed. The on/off timings of the fifth switch SW5, the eleventh switch SW11, the twelfth switch SW12, and the thirteenth switch SW13 in the first sawtooth wave circuit 931 are the same as the on/off timings of the fifth switch SW5, the eleventh switch SW11, the twelfth switch SW12, and the thirteenth switch SW13 in the non-sinusoidal signal generation apparatus 700 according to the second embodiment, respectively. In addition, the second sawtooth wave circuit 932 is the same as the sawtooth wave circuit 730 in the non-sinusoidal signal generation apparatus 700 according to the second embodiment except that the fifth voltage source VS5 and the fifth switch SW5 are removed. The on/off timings of the sixth switch SW6, the fourteenth switch SW14, the fifteenth switch SW15, and the sixteenth switch SW16 in the second sawtooth wave circuit 932 are the same as the on/off timings of the sixth switch SW6, the eleventh switch SW11, the twelfth switch SW12, and the thirteenth switch SW13 in the non-sinusoidal signal generation apparatus 700 according to the second embodiment, respectively. Each of the inductors L1 and L2 may have the same inductance as the inductance of the inductor L of the sawtooth wave circuit 730 in the second embodiment. Therefore, further detailed description of the sawtooth wave circuit 930 in the fourth embodiment is omitted.

On the other hand, in the description with reference to FIGS. 2 to 9, the circuit may be configured in various forms, e.g., being implemented by omitting VS4 and VS6 or by omitting VS2, VS4, and VS6.

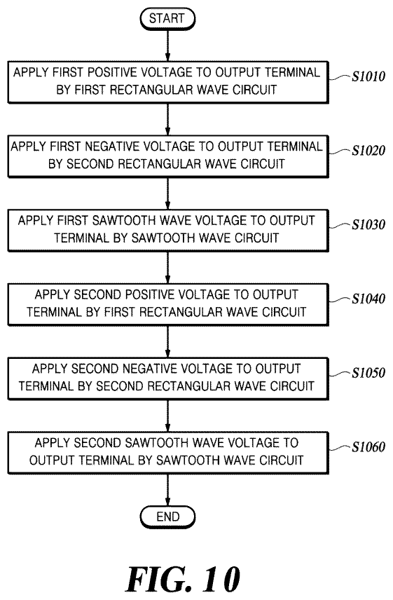

FIG. 10 is a flowchart of a method for generating a non-sinusoidal signal according to the present embodiment.

A first positive voltage is applied to the output terminal Nout by the first rectangular wave circuit 110 (S1010). The controller 140 turns on and off the switches in the non-sinusoidal signal generation apparatus 100 to provide the positive voltage V1 having a first magnitude to the output terminal Nout.

A first negative voltage is applied to the output terminal Nout by the second rectangular wave circuit 120 (S1020). The controller 140 turns on and off the switches in the non-sinusoidal signal generation apparatus 100 to provide the negative voltage V3 having the first magnitude to the output terminal Nout.

A first sawtooth wave voltage is applied to the output terminal Nout by the sawtooth wave circuit 130 (S1030). The controller 140 turns on and off the switches in the non-sinusoidal signal generation apparatus 100 to provide a first sawtooth wave voltage having a maximum magnitude of −V3-Vt1 to the output terminal Nout.

A second positive voltage is applied to the output terminal Nout by the first rectangular wave circuit 110 (S1040). The controller 140 turns on and off the switches in the non-sinusoidal signal generation apparatus 100 to provide the positive voltage V2 having a second magnitude to the output terminal Nout.

A second negative voltage is applied to the output terminal Nout by the second rectangular wave circuit 120 (S1050). The controller 140 turns on and off the switches in the non-sinusoidal signal generation apparatus 100 to provide the negative voltage V4 of the second magnitude to the output terminal Nout.

A second sawtooth wave voltage is applied to the output terminal Nout by the sawtooth wave circuit 130 (S1060). The controller 140 turns on and off the switches in the non-sinusoidal signal generation apparatus 100 to provide the second sawtooth wave voltage having a maximum magnitude of −V4-Vt2 to the output terminal Nout.

In the process of providing the first and second sawtooth wave voltages, the controller 140 controls the current to be drawn from the capacitive load connected to the output terminal Nout by using the inductor L included in the sawtooth wave circuit 130.

The method for generating a non-sinusoidal signal according to the present embodiment may be similarly performed by the non-sinusoidal signal generating apparatuses 700, 800, and 900 according to the second to fourth embodiments.

The description of steps S1010 to S1060 has been provided in the description of the first rectangular wave circuit 110, the second rectangular wave circuit 120, and the sawtooth wave circuit 130. Thus, further detailed description is omitted.

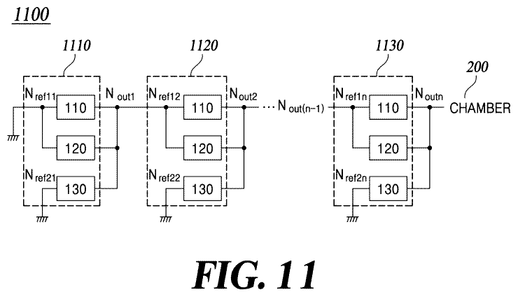

FIG. 11 is a diagram illustrating an example of a non-sinusoidal signal generation apparatus implemented by connecting a plurality of first rectangular wave circuits, a plurality of second rectangular wave circuits, and a plurality of sawtooth wave circuits in series.

As shown in FIG. 11, n unit circuits (i.e., a first circuit 1110, a second circuit 1120, . . . , and an n^{th} circuit 1130) may be connected in series to implement the non-sinusoidal signal generation apparatus 1100. For reference, a controller (not shown) is omitted in FIG. 11.

The n unit circuits 1110, 1120, and 1130 each include a first rectangular wave circuit 110, a second rectangular wave circuit 120, and a sawtooth wave circuit 130 and are connected as shown in FIG. 11 so that the n^{th} circuit 1130 at the end outputs a non-sinusoidal signal to the chamber 200.

In the first circuit 1110, a first reference terminal Nef11 and a second reference terminal Nef21 are connected to the ground. In the second circuit 1120, a first reference terminal Nef12 is connected to an output terminal Nout1 of the first circuit 1120, and a second reference terminal Nef22 is connected to the ground. In the n^{th} circuit 1130, a first reference terminal Nref1n is connected to an output terminal Nout(n−1) of an (n−1)^{th} circuit (not shown), a second reference terminal Nref2n is connected to the ground, and an output terminal Noutn is connected to the chamber 200.

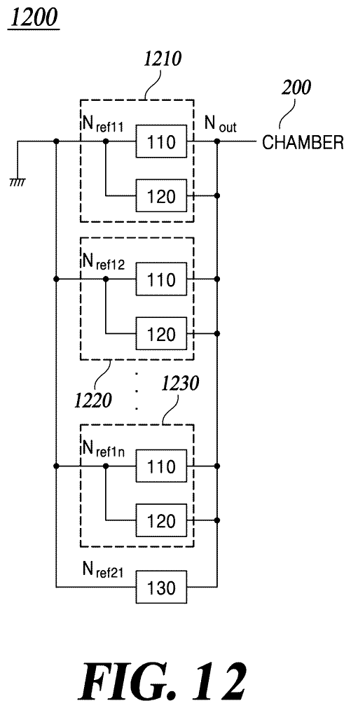

FIG. 12 is a diagram illustrating an example of a non-sinusoidal signal generation apparatus implemented by connecting a plurality of first rectangular wave circuits, a plurality of second rectangular wave circuits, and one sawtooth wave circuit in parallel.

As shown in FIG. 12, n unit circuits (i.e., a first circuit 1210, a second circuit 1220, . . . , and an n^{th} circuit 1230) and the sawtooth wave circuit 130 are connected in parallel to implement a non-sinusoidal signal generation apparatus 1200. For reference, a controller (not shown) is omitted in FIG. 12.

The n unit circuits 1210, 1220, and 1230 each include a first rectangular wave circuit 110 and a second rectangular wave circuit 120.

Each of the first reference terminals Nref11, Nref12, . . . , and Nref1n of the first to n^{th} unit circuits 1210, 1220, and 1230 and the second reference terminal Nref2 of the second rectangular wave circuit 120 is connected to the ground. The first to n^{th} unit circuits 1210, 1220, and 1230 and the second rectangular wave circuit 120 are each connected to the output terminal as shown in FIG. 2 to output a non-sinusoidal signal to the chamber 200.

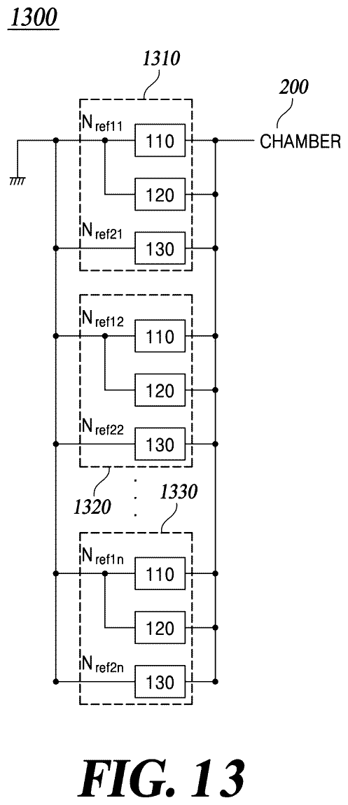

FIG. 13 is a diagram illustrating an example of a non-sinusoidal signal generation apparatus implemented by connecting a plurality of first rectangular wave circuits, a plurality of second rectangular wave circuits, and a plurality of sawtooth wave circuits in parallel.

As shown in FIG. 13, n unit circuits (i.e., a first circuit 1310, a second circuit 1320, . . . , and an n^{th} circuit 1330) may be connected in parallel to implement a non-sinusoidal signal generation apparatus 1300. For reference, a controller (not shown) is omitted in FIG. 13.

The n unit circuits 1310, 1320, and 1330 each include a first rectangular wave circuit 110, a second rectangular wave circuit 120, and a sawtooth wave circuit 130.

In the first to n^{th} unit circuits 1310, 1320, and 1330, each of the first reference terminals Nref11, Nref12, . . . , and Nref1n and each of the second reference terminals NRef21, Nref22, . . . , and Nref2n are connected to the ground and are connected to the output terminal, as shown in FIG. 2, to output a non-sinusoidal signal to the chamber 200.

In FIG. 11 to FIG. 13, instead of the first rectangular wave circuit 110, the second rectangular wave circuit 120, and the sawtooth wave circuit 130, the first rectangular wave circuit 710, the second rectangular wave circuit 720, and the sawtooth wave circuit 730 may be used, respectively, the first rectangular wave circuit 810, the second rectangular wave circuit 820, and the sawtooth wave circuit 830 may be used respectively, or the first rectangular wave circuit 910, the second rectangular wave circuit 920, and the sawtooth wave circuit 930 may be used, respectively.

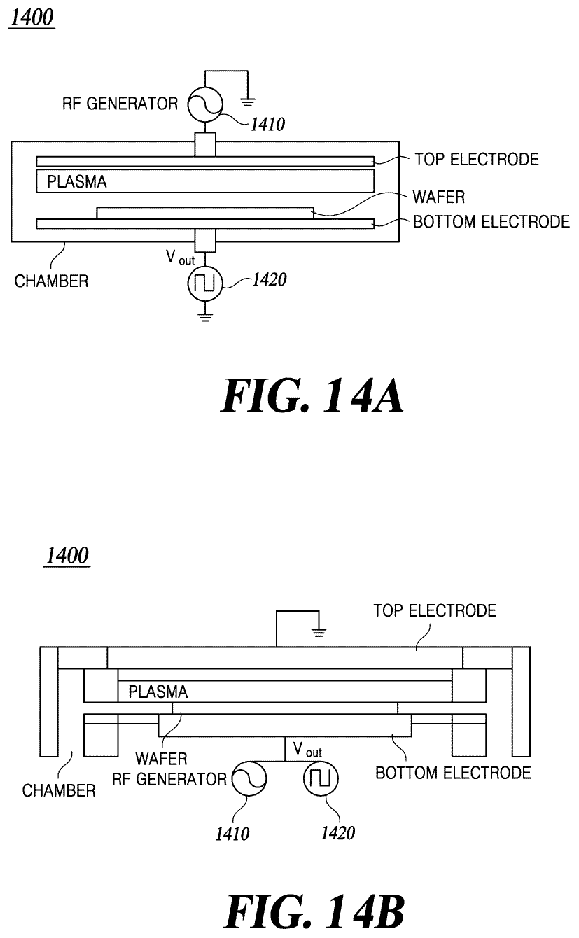

FIGS. 14A and 14B are block diagrams of an apparatus for manufacturing a semiconductor device 1400 according to the present embodiment.

Referring to FIG. 14A, the apparatus for manufacturing a semiconductor device 1400 may include a chamber CB, a first power generator 1410, and a second power generator 1420.

A top electrode TE may be arranged in an upper region of the chamber CB, a bottom electrode BE may be arranged in a lower region of the chamber CB, and a wafer W may be disposed on top of the bottom electrode BE.

The bottom electrode BE may be an electrostatic chuck (ESC) that adsorbs and supports the wafer W by electrostatic force. In addition, the chamber CB may include a gas supply unit and a gas discharge unit, wherein the gas supply unit may supply a reaction gas into the chamber CB and the gas discharge unit may discharge the gas to maintain the chamber CB in a vacuum state.

The first power generator 1410 may generate a first power and may provide the generated first power to the top electrode TE. The first power, which is a power for generating plasma, may be referred to as a source power. The first power generator 1410 may be a device that generates a high-frequency power source in the form of a sinusoidal wave of several tens of MHz.

The second power generator 1420 may generate a second power in a non-sinusoidal form. The second power, which is a power for controlling ion energy of the plasma, may be referred to as a bias power.

When the second power is provided to the bottom electrode BE, a voltage may be induced to the wafer W disposed on the bottom electrode BE. Accordingly, the voltage of the wafer W may be controlled according to the second power, thereby controlling the ion energy of the plasma generated in the chamber CB.

In the present embodiment, the second power generator 1420 may generate any waveform of high voltage and high speed set by the user. For example, the second power generator 1420 may generate a voltage having a certain waveform having a voltage level of several tens of V to several tens of kV at a frequency of several kHz to several MHz. The second power generator 1420 may be implemented by using the non-sinusoidal signal generation apparatuses 100, 200, 700, 800, 900, 1100, 1200, and 1300 in FIG. 1, FIG. 2, FIG. 7, FIG. 8, FIG. 9, FIG. 11, FIG. 12, and FIG. 13. The descriptions described above with reference to FIG. 1 to FIG. 13 may be applied to the second power generator 1420.

Specifically, the second power generator 1420 may include at least one first rectangular wave circuit, at least one second rectangular wave circuit, and at least one slope circuit, wherein the at least one first rectangular wave circuit, the at least one second rectangular wave circuit, and the least one slope circuit may be connected in any one of the manners shown in FIG. 1, FIG. 2, FIG. 7, FIG. 8, FIG. 9, FIG. 11, FIG. 12, and FIG. 13.

As shown in FIGS. 1 and 11 to 13, the second power generator 1420 may include a plurality of first rectangular wave circuits, a plurality of second rectangular wave circuits, and a plurality of slope circuits.

The magnitude distribution of the ion energy generated by the second power generator 1410 may be determined based on the number of first rectangular wave circuits, the number of second rectangular wave circuits, and the number of sawtooth wave circuits. Therefore, the number of first rectangular wave circuits and second rectangular wave circuits to be activated among the plurality of first rectangular wave circuits and the plurality of second rectangular wave circuits, and the number of sawtooth wave circuits to be activated among the plurality of sawtooth wave circuits may be determined based on the target magnitude of magnitude distribution of the ion energy.

In addition, the distribution of the ion energy may be determined according to a waveform of the sawtooth wave voltage output from the sawtooth wave circuit. Accordingly, switch driving signals generated by the controller (e.g., the controller 140 of FIG. 1) in the second power generator 1420 may be controlled according to the target distribution of ion energy. For example, the second power generator 1420 may control the switch to output a waveform of the sawtooth wave voltage such that plasma ions are distributed over a narrow energy region.

On the other hand, unlike in FIG. 14A, the apparatus for manufacturing a semiconductor device 1400 may be implemented to provide the first power generated by the first power generator 1410 to the bottom electrode BE as illustrated in FIG. 14B.

In FIGS. 14A and 14B, the apparatus for manufacturing a semiconductor device 1400 may further include a filter between the second power generator 1420 and the bottom electrode BE. The filter may cut off the first power so that the first power generated by the first power generator 1410 is not applied to the second power generator 1420 and may pass the second power so that the second power generated by the second power generator 1420 is applied to the bottom electrode BE. Specifically, the filter may remove a frequency component of RF power generated by the first power generator 1410. For example, the filter may be configured as a low pass filter, a band stop filter, or a combination of the low pass filter and the band stop filter.

In addition, in FIG. 14A, the apparatus for manufacturing a semiconductor device 1400 may further include a filter between the first power generator 1410 and the top electrode TE. The filter may cut off the second power so that the second power generated by the second power generator 1420 is not applied to the first power generator 1410 and may pass the first power so that the first power generated by the first power generator 1410 is applied to the top electrode TE.

In addition, in FIG. 14B, the apparatus for manufacturing a semiconductor device 1400 may further include a filter between the first power generator 1410 and the bottom electrode BE. The filter may cut off the second power so that the second power generated by the second power generator 1420 is not applied to the first power generator 1410 and may pass the first power so that the first power generated by the first power generator 1410 is applied to the bottom electrode BE.

The filter may be configured as a low pass filter, a band stop filter, or a combination of the low pass filter and the band stop filter.

The reaction gas may be diffused in the chamber CB and converted into plasma by the first power applied through the top electrode TE or the bottom electrode BE and the second power applied through the bottom electrode BE. The plasma is brought into contact with the surface of the wafer W to physically or chemically react. Through this reaction, a wafer processing process, such as plasma annealing, etching, plasma-enhanced chemical vapor deposition, physical vapor deposition, and plasma cleaning, may be performed.

When the apparatus for manufacturing a semiconductor device 1400 is used in the etching process, the reaction gas is plasmaized by high-frequency discharge between the bottom electrode BE and the top electrode TE. A film to be processed on the wafer W may be etched in a desired pattern by radicals, electrons, and ions activated by the plasma. According to the present embodiment, by precisely controlling the radicals, electrons, and ions of the plasma, etching performance, such as an etching rate, an aspect ratio, a critical dimension of an etching pattern, a profile of the etching pattern, and a selectivity, may be improved.

On the other hand, various functions or methods described in this disclosure may be implemented with instructions stored in a non-transitory recording medium, which can be read and executed by one or more processors. The non-transitory recording medium includes all kinds of recording devices where data is stored, e.g., in a form readable by a computer system. For example, the non-transitory recording medium includes a storage medium, such as an erasable programmable read-only memory (EPROM), a flash drive, an optical drive, a magnetic hard drive, and a solid-state drive (SSD).

It should be understood that the example embodiments above may be implemented in many different ways. The functions described in one or more examples may be implemented in hardware, software, firmware, or any combination thereof. It should be understood that the functional components described herein have been labeled “unit” to particularly emphasize their implementation independence.

The above description is merely illustrative of the technical idea of the present embodiment, and various modifications and variations will be possible to those skilled in the art without departing from the essential characteristics of the present embodiment. Therefore, the present embodiments are not intended to limit but to explain the technical idea of the present embodiment, and the scope of the technical idea of the present embodiment is not limited by the present embodiment. The protection scope of the present embodiment should be interpreted by the following claims, and all technical ideas falling within the scope equivalent thereto should be interpreted as being included in the scope of rights of the present embodiment.

What is claimed is:

1. A non-sinusoidal signal generation apparatus comprising:
a first square wave circuit, which can apply, to an output terminal, two positive voltages having different magnitudes;
a second square wave circuit, which can apply, to the output terminal, two negative voltages having different magnitudes; and
a sawtooth wave circuit, which can apply, to the output terminal, two sawtooth wave voltages having different magnitudes,
wherein the sawtooth wave circuit includes an inductor for drawing current from a capacitive load connected to the output terminal.

2. The non-sinusoidal signal generation apparatus of claim 1,
wherein the first square wave circuit comprises a first voltage source circuit and a second voltage source circuit connected in parallel, each of which generates two positive voltages having different magnitudes, by connecting a negative terminal to a reference terminal, wherein the first voltage source circuit comprises a first voltage source and a first switch connected in series, and the second voltage source circuit comprises a second voltage source and a second switch connected in series,
wherein the second square wave circuit comprises a third voltage source circuit and a fourth voltage source circuit, each of which generates two negative voltages having different magnitudes, by connecting a positive terminal to the reference terminal, wherein the third voltage source circuit comprises a third switch and a third voltage source connected in series, and wherein the fourth voltage source circuit comprises a fourth switch and a fourth voltage source connected in series.

3. The non-sinusoidal signal generation apparatus of claim 2,
wherein, in the first square wave circuit, seventh and eighth switches connected in series are connected to a positive terminal of the first voltage source circuit,
and in the second square wave circuit, tenth and ninth switches connected in series are connected to a negative terminal of the third voltage source circuit.

4. The non-sinusoidal signal generation apparatus of claim 3,
wherein the first square wave circuit further comprises a first diode having an anode connected to the reference terminal and a cathode connected between the seventh and eighth switches.

5. The non-sinusoidal signal generation apparatus of claim 3,
wherein the second square wave circuit further comprises a second diode having a cathode connected to the reference terminal and an anode connected between the ninth and tenth switches.

6. The non-sinusoidal signal generation apparatus of claim 3,
further comprising a third diode connected between the ninth switch and the output terminal,
wherein the eighth switch is connected to the output terminal.

7. The non-sinusoidal signal generation apparatus of claim 2,
wherein the first square wave circuit comprises a seventh switch having one end connected to a positive terminal of the first voltage source circuit and a positive terminal of the second voltage source circuit,
and the second square wave circuit comprises a tenth switch having one end connected to a negative terminal of the third voltage source circuit and a negative terminal of the fourth voltage source circuit.

8. The non-sinusoidal signal generation apparatus of claim 1,
wherein the sawtooth wave circuit comprises a fifth voltage source circuit and a sixth voltage source circuit, each of which generates two negative voltages having different magnitudes, by connecting a positive terminal to a reference terminal, wherein the fifth voltage source circuit comprises a fifth voltage source and a fifth switch connected in series, and the sixth voltage source circuit comprises a sixth voltage source and a sixth switch connected in series,
wherein one end of an eleventh switch is connected to a negative terminal of the fifth voltage source circuit, a fourth diode is connected between the other end of the eleventh switch and the reference terminal, one end of the inductor is connected to the other end of the eleventh switch, a twelfth switch and a fifth diode are connected in series between the other end of the inductor and the reference terminal, and a thirteenth switch is connected between the other end of the inductor and the output terminal.

9. The non-sinusoidal signal generation apparatus of claim 8,
wherein, in the sawtooth wave circuit,
one of the fifth voltage source and the sixth voltage source is connected to a circuit by the fifth switch and the sixth switch, current flows from the connected voltage source to the inductor, and a capacitive load connected to the output terminal is discharged by using the current flowing to the inductor to apply the sawtooth wave voltage to the output terminal.

10. A method for generating a non-sinusoidal signal by an apparatus comprising a first square wave circuit, a second square wave circuit, and a sawtooth wave circuit, the method comprising:
applying a first positive voltage to an output terminal by the first square wave circuit;
applying a first negative voltage to the output terminal by the second square wave circuit;
applying a first sawtooth wave voltage to the output terminal by the sawtooth wave circuit;
applying a second positive voltage to the output terminal by the first square wave circuit;
applying a second negative voltage to the output terminal by the second square wave circuit; and
applying a second sawtooth wave voltage to the output terminal by the sawtooth wave circuit, wherein, when the first sawtooth wave voltage or the second sawtooth wave voltage is applied, current is drawn from a capacitive load connected to the output terminal by using an inductor included in the sawtooth wave circuit.

11. An apparatus for manufacturing a semiconductor device comprising a non-sinusoidal signal generation apparatus and a chamber,
wherein the non-sinusoidal signal generation apparatus comprises:
a first square wave circuit, which can apply, to an output terminal, two positive voltages having different magnitudes;
a second square wave circuit, which can apply, to the output terminal, two negative voltages having different magnitudes;
and a sawtooth wave circuit, which can apply, to the output terminal, two sawtooth wave voltages having different magnitudes,
wherein the sawtooth wave circuit comprises an inductor for drawing current from a capacitive load connected to the output terminal.
